(19) United States
(12) Patent Application Publication
(10) Pub. No.: US 2018/0322994 A1
(43) Pub. Date: Nov. 8, 2018

(54) THERMAL BUDGET ENHANCEMENT OF A MAGNETIC TUNNEL JUNCTION

(71) Applicant: Intel Corporation, Santa Clara, CA (US)

(72) Inventors: Tofizur RAHMAN, Portland, OR (US); Christopher J. WIEGAND, Portland, OR (US); Daniel B. BERGSTROM, Lake Oswego, OR (US)

(73) Assignee: Intel Corporation, Santa Clara, CA (US)

(21) Appl. No.: 15/773,339

(22) PCT Filed: Dec. 7, 2015
(86) PCT No.: PCT/US2015/064182

§ 371 Date: May 3, 2018

(51) Int. Cl. H01F 10/32; G11C 11/16; H01L 43/02; H01L 43/10; H01L 43/12; H01L 27/22; H01F 41/32

(52) U.S. Cl. CPC H01F 10/3254; G11C 11/161; H01L 43/02; H01F 41/32; H01L 43/12; H01L 27/222; H01F 10/3272; H01L 43/10

(57) ABSTRACT

Embodiments of the disclosure are directed to a magnetic tunneling junction (MTJ) that includes a diffusion barrier. The diffusion barrier can be disposed between two ferromagnetic layers of the MTJ. More specifically, the diffusion barrier can be disposed between a first ferromagnetic layer, which is adjacent to a natural antiferromagnetic layer, and a second ferromagnetic layer; the first and second ferromagnetic layers and the diffusion barrier being part of a synthetic antiferromagnet. The diffusion barrier can be made of a refractory metal, such as tantalum. The diffusion barrier acts as a barrier for manganese diffusion from the natural antiferromagnetic layer into the synthetic antiferromagnet and other higher layers of the MTJ.

### TECHNICAL FIELD

This disclosure pertains to magnetic tunnel junctions, and more particularly, to increasing the thermal stability of a magnetic tunnel junction.

### BACKGROUND

The fabrication of magnetic tunnel junction devices (MTJs), such as may be utilized in magnetic random access memory (MRAM) devices, typically include a top and bottom ferromagnetic electrodes separated by a tunnel barrier layer. The MRAM device operates by electrons tunneling through the barrier layer between the two ferromagnetic electrodes. During fabrication of MTJs and integration with complementary metal-oxide semiconductor (CMOS), high temperature thermal processes may result in a drop or loss of tunneling magneto-resistance and an increase in resistance-area product.

### BRIEF DESCRIPTION OF THE DRAWINGS

FIG. 1 is a schematic block diagram of a magnetic tunneling junction (MTJ) in accordance with embodiments of the present disclosure.

FIG. 2 is a schematic block diagram of a magnetic tunneling junction (MTJ) in accordance with embodiments of the present disclosure.

FIG. 3-1 is a process flow diagram for forming a magnetic tunneling junction that includes a diffusion layer.

FIG. 3-2 is a continuation of the process flow diagram of FIG. 301 for forming a magnetic tunneling junction that includes a diffusion layer.

FIG. 4 is an interposer implementing one or more embodiments of the disclosure.

FIG. 5 is a computing device built in accordance with an embodiment of the disclosure.

FIG. 6 is an example transmission electron micrograph of a diffusion barrier between two ferromagnetic layers of a magnetic tunneling junction.

### DETAILED DESCRIPTION

One mode of thermal degradation in state-of-the-art magnetic tunnel junction (MTJ) devices is via atomic diffusion of one or more elements in the multilayer stack. In particular manganese from an antiferromagnetic pinning layer can be mobile at temperatures exceeding 400 C. This disclosure describes adding a refractory metal layer of a determined thickness at a location in the multilayer MTJ stack that acts as a diffusion barrier while simultaneously allowing the MTJ stack to maintain key magnetic properties necessary for its function.

MTJ devices lack a diffusion barrier between an antiferromagnetic layer containing manganese and the other magnetic layers in the MTJ stack. As a result, thermal degradation in these MTJ stacks begins around 400 C whereby area resistance rises and tunnel magnetoresistance ratio falls, both of which are undesirable to proper device function. Diffusion of manganese (Mn) into the synthetic antiferromagnetic layer can diminish the coupling strength that may make the reference layer unstable and cause reduction of TMR at certain switching field. The Mn diffusion into tunnel barrier layer also may cause a reduction in tunneling magnetoresistance (TMR) of the MTJ and increase the resistance-area product of the MTJ. These consequences can degrade the ability of the MTJ to act as a memory element.

In some embodiments, a layer of tantalum (Ta), which is a refractory metal, can act as a diffusion barrier. The diffusion barrier of Ta can be of a thickness on the order of 1-10 Angstroms (Å). The diffusion barrier can be detected using transmission electron microscopy (TEM) with element filtering via energy dispersive X-ray spectroscopy (EDX) or electron energy loss spectroscopy (EELS). Such techniques would reveal the use of a refractory metal or refractory metal nitride diffusion barrier in the MJT, such as in embodiments in which the diffusion barrier is disposed between ferromagnetic layers adjacent to the natural antiferromagnetic layer. The term “disposed” in this disclosure can mean reside, formed, sputtered, deposited, exist, sit, rest, be in physical contact with, or otherwise positioned.

Described herein are systems and methods of increasing the thermal stability of a magnetic tunneling junction (MTJ). In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

Implementations of the disclosure may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present disclosure.

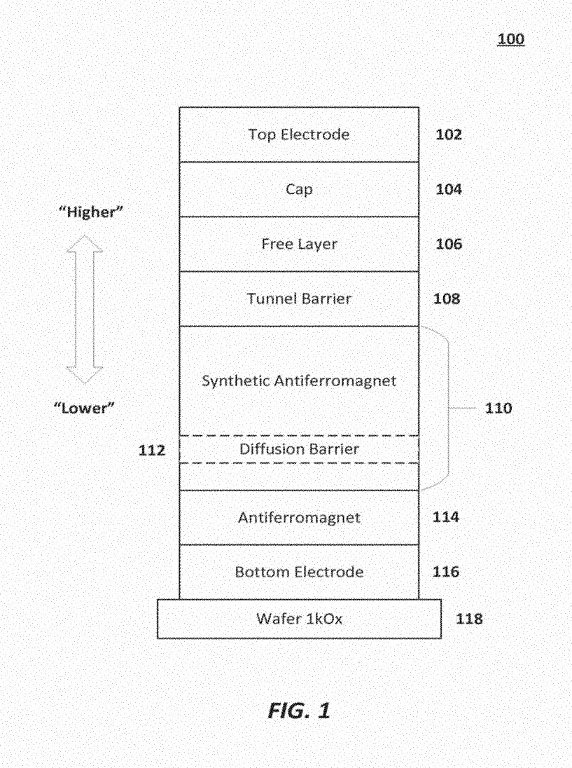

FIG. 1 is a schematic block diagram of a magnetic tunneling junction (MTJ) 100 in accordance with embodiments of the present disclosure. The MTJ STACK 100 includes a top electrode 102, a cap 104, a free layer 106 (also known as a storage layer), a tunnel barrier 108, a synthetic antiferromagnet 110, an antiferromagnet 114, and a bottom electrode 116. The MTJ STACK 100 can be formed on a substrate 118, such as a silicon oxide substrate. The silicon oxide substrate 118 can be on the order of 1000 Å. The antiferromagnet 114 can be a natural antiferromagnet. The bottom electrode 116 can include one or more layers of discrete elements or compounds.

The various MTJ layers can be formed via in-vacuum sputtering deposition techniques and photolithography. Other deposition techniques can also be used, such as physical vapor deposition (PVD), chemical vapor deposition, molecular beam epitaxy, pulsed laser deposition, electron beam PVD, etc. Other processing techniques can be used in addition, such as dry etching, wet etching, ion-beam etching, etc.

The term “layer” is used herein to describe portions of the MJT 100. The term “layer” can include one or more atomic layers of an element or compound. The term layer can also mean a discrete portion of the MJT, such as the synthetic antiferromagnetic layer, which would include one or more sub-layers of elements or compounds.

The top electrode 102 and the bottom electrode 116 allow electrical conductivity through the MTJ stack 100. In the example shown in FIG. 1, current flows from the top electrode 102 to the bottom electrode 116. The MTJ stack 100 can respond to an external magnetic field by changing the direction of magnetization between the free layer 106 and the reference layers (one or both of the synthetic antiferromagnet or the natural antiferromagnet or both). By controlling the magnetization direction in the MTJ stack 100, the MTJ can have a switchable electrical resistance (e.g., low resistance or high resistance) between the top electrode and the bottom electrode.

The free layer 106 provides a low switching field and free to move from north to south and vice versa relative to synthetic antiferromagnetic (SAF) layer for the MTJ stack 100. The synthetic antiferromagnet 110 provides higher switching field and fixed the magnetization in one direction through pinning with the antiferromagnetic layer 114. The synthetic antiferromagnet 110 can include a diffusion barrier 112. The diffusion barrier 112 can include a material that 1) acts as a barrier to diffusion of elements from the antiferromagnet 114, and 2) maintains the strongly ferromagnetic coupling between portions of the synthetic antiferromagnet 110 and the antiferromagnet 114; and 3) maintains the magnetic properties of the synthetic antiferromagnet 110.

The term “higher” is meant to represent a direction towards the top electrode 102; while the term “lower” is meant to represent a direction towards the wafer 118. The terms higher and lower are used for illustrative purposes only to indicate a direction or location. For example, the direction of the electrical current may conduct from higher layers of the MTJ stack 100 to lower layers of the MTJ stack 100, meaning that the direction of the electrical current would be from the top electrode 102 to the bottom electrode 116. Other terms may coincide with higher and lower. For example, the term “above” may coincide with being higher; while “below” may coincide with being lower. In MTJ stack 100, for example, the top electrode 102 is above the cap 104; the free layer 106 is below the cap 104.

The diffusion barrier 112 includes properties that prevent diffusion of materials from the antiferromagnet 114 from diffusing in a direction towards the “higher” portions of the synthetic antiferromagnet 110 during an anneal process where annealing temperature can exceed 400 C. The diffusion barrier 112 can be of a thickness and material that prevents or mitigates diffusion from the antiferromagnet 114 while also maintaining magnetic properties of the MTJ stack 100. More specifically, the diffusion barrier is structured so that the strongly ferromagnetic coupling between the synthetic antiferromagnet 110 and the natural antiferromagnet 114 is maintained. In some embodiments, the synthetic antiferromagnet 110 and the natural antiferromagnet 114 have a magnetic exchange bias at or above 550 Oersted.

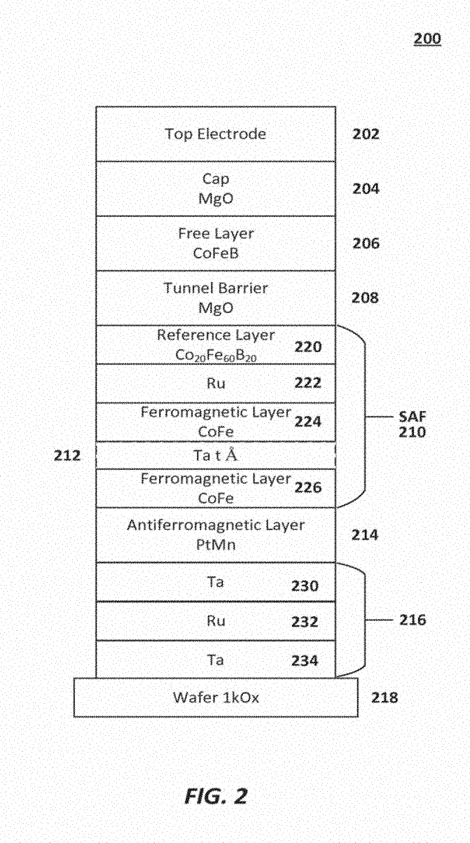

FIG. 2 is a schematic block diagram of a magnetic tunneling junction (MTJ) stack 200 in accordance with embodiments of the present disclosure. The MTJ stack 200 includes a top electrode 202, a cap 204, a free layer 206 (also known as a storage layer), a tunnel barrier 208, a synthetic antiferromagnet 210, an antiferromagnet 214, and a bottom electrode 216. The MTJ stack 200 can be formed on a substrate 218, such as a silicon oxide substrate.

In FIG. 2, the synthetic antiferromagnet 210 provides a zero moment situation by oppositely coupling the ferromagnetic and antiferromagnetic layer for the MTJ stack 200. The synthetic antiferromagnet 210 includes a reference layer 220 having an opposite magnetism direction to the ferromagnetic layer 224 and 226. In some embodiments, reference layer 220 includes Co₂₀Fe₆₀B₂₀. The synthetic antiferromagnet 210 also includes a second ferromagnetic layer 224 and a first ferromagnetic layer 226. The synthetic antiferromagnet 210 is above and adjacent to an antiferromagnetic layer 214. The antiferromagnetic layer 214 can interact with the synthetic antiferromagnet 210 to create large switching field; the antiferromagnetic layer 214 can be strongly magnetically coupled with the synthetic antiferromagnet 210 through the first ferromagnetic layer 226 of the synthetic antiferromagnet 210.

The antiferromagnetic layer 214 can include platinum manganese (PtMn). In some embodiments, the antiferromagnetic layer 214 can include other alloys of manganese, such as Iridium manganese (IrMn), iron manganese (FeMn), nickel manganese (NiMn), etc. that have characteristics of a natural antiferromagnet and can be strongly ferromagnetically coupled to the first ferromagnetic layer 226. Additionally, the antiferromagnetic layer 214 can include magnetic spin aligned in a same direction as the first ferromagnetic layer 226, and in embodiments, in a same direction as the second ferromagnetic layer 224. Ferromagnetic layer 224 and 226 are strongly ferromagnetically coupled through the diffusion barrier layer 212.

The second ferromagnetic layer 224 and the first ferromagnetic layer 226 can include alloys of cobalt (Co) and iron (Fe): CoₓFe_{y}.

A diffusion barrier 212 is disposed between the second ferromagnetic layer 224 and the first ferromagnetic layer 226. The diffusion barrier 212 includes properties that prevent diffusion of manganese from the antiferromagnet 214 from diffusing in a direction towards the “higher” portions of the synthetic antiferromagnet 210 during an anneal process where annealing temperature can exceed 400 C. The diffusion barrier 212 can be of a thickness and material that prevents or mitigates diffusion from the antiferromagnet 214 while also maintaining magnetic properties of the MTJ stack 100. More specifically, the diffusion barrier is structured so that the strong ferromagnetic coupling between the first ferromagnetic layer 226 and the natural antiferromagnet 214 is maintained. Specifically, the strong magnetic coupling between the antiferromagnetic layer 214 and the ferromagnetic layer 224 is maintained, even in the presence of the diffusion barrier 212. In some embodiments, the synthetic antiferromagnet 110 and the natural antiferromagnet 214 have a magnetic exchange bias at or above 550 Oersted.

For example, the diffusion barrier 212 can include a refractory metal, such as tantalum (Ta). Other refractory metals that can be used for the diffusion barrier include Molybdenum, Tungsten, Niobium, Hafnium, Zirconium, or Titanium, as well as corresponding nitrides for the aforementioned metals.

In some embodiments, the diffusion barrier 212 can have a thickness “t” (i.e., sizing dimension between the second ferromagnetic layer 224 and the first ferromagnetic layer 226) on the order of several angstroms. In some embodiments, the thickness can include a thickness in a range from 1 Å to 10 Å. In some embodiments, the diffusion barrier 212 can have a thickness on the order of 4-6 Å. In some embodiments the diffusion barrier 212 can have a thickness of 5 Å.

The MTJ stack 200 includes a free layer 206 that can include CoFeB or other magnetic materials. The MTJ stack 200 also includes a tunnel barrier 208 disposed between the free layer 206 and the synthetic antiferromagnet 210. The tunnel barrier 208 can include magnesium oxide (MgO) or Aluminum Oxide (Al₂O₃). The MTJ stack 200 includes a cap 204 that includes MgO or other metal oxides or refractory metals. The cap 204 is disposed between the top electrode 202 and the free layer 206. Cap 204 protects the free layer 206 from the damage that may cause during top electrode deposition.

The bottom electrode 216 can include a top layer 230 that includes a refractory metal, such as Ta. The bottom electrode 216 also includes a ruthenium layer 232 and bottom layer 234, which can also include Ta. The top layer 230 material can be chosen based on the crystal structure matching for the natural antiferromagnet 214. For example, Ta can be used for aiding in the layer formation of a PtMn antiferromagnet.

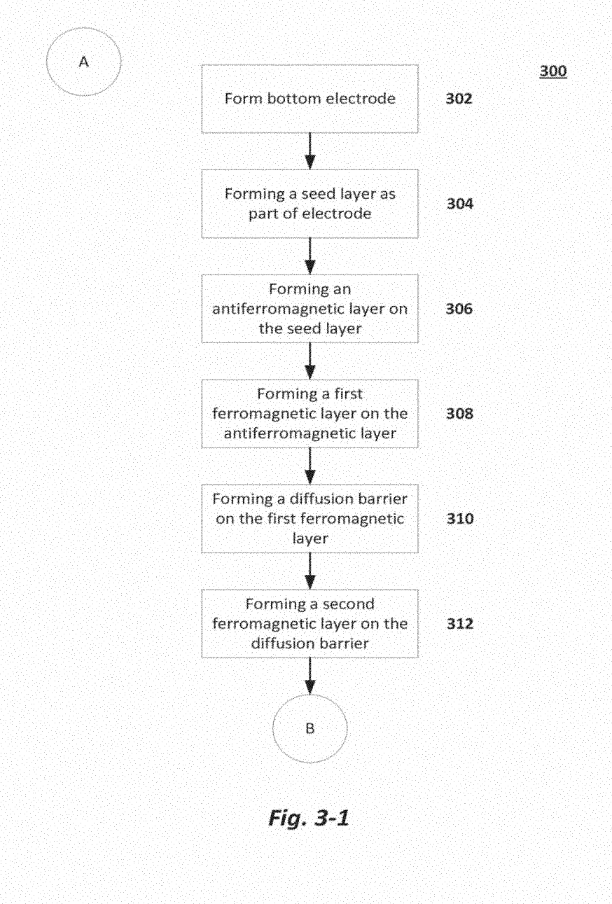

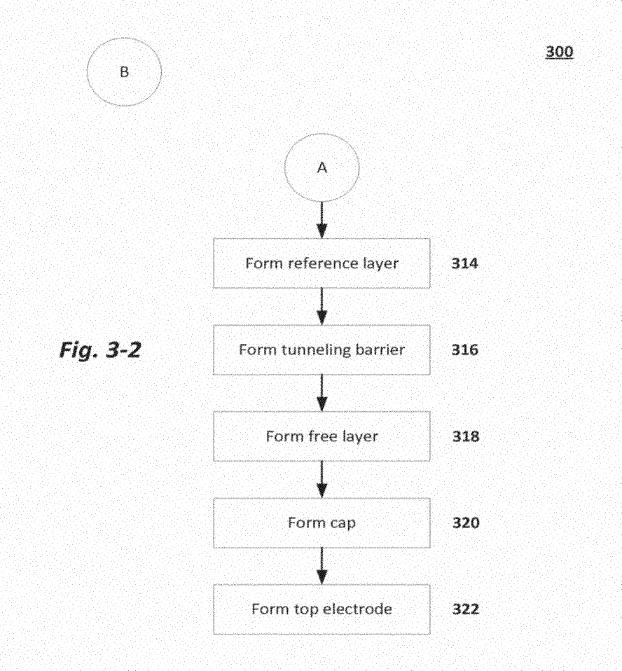

FIG. 3 is a process flow diagram 300 for forming a magnetic tunneling junction that includes a diffusion layer. On a silicon oxide substrate, an electrode can be formed (302). The electrode can be formed by forming a layer of metal, such as tantalum, on the silicon oxide. A layer of ruthenium can be formed on the tantalum.

A seed layer can be formed as part of the electrode (304). The seed layer can be selected based on the materials to be used to help to grow the subsequent antiferromagnet. For example, Ta can be used as a seed layer when the subsequent antiferromagnet is composed of PtMn. Other seed layer materials can be used depending on the material used for the antiferromagnetic layer. Additionally, the seed layer can act as a diffusion barrier for Mn diffusing into lower layers of the bottom electrode. For example, a refractory metal such as Ta can be used as the seed layer, which acts as a diffusion barrier for Mn to prevent the deterioration of the antiferromagnetic properties of PtMn.

The antiferromagnetic layer can be formed on the seed layer (306). The antiferromagnetic layer can be PtMn or other alloys of Mn (e.g., IrMn, FeMn, NiMn, CrPdMn, etc.). The antiferromagnetic layer can be a natural antiferromagnet. The antiferromagnet can be heated above 350 C. At temperatures above 350 C, the magnetic spin can be aligned by applying a magnetic field. The antiferromagnetic can be cooled in the presence of the magnetic field to lock the magnetic spin direction along the applied magnetic field.

A synthetic antiferromagnet can be formed on the antiferromagnetic layer. A first ferromagnetic layer can be formed on the antiferromagnetic layer (308). The antiferromagnetic layer pins the magnetism of the first ferromagnetic layer.

A diffusion barrier can be formed on the first ferromagnetic layer (310). The diffusion barrier can be formed using a refractory metal, such as Ta, Mo, W, Hf, Ti, Zr, Nb, etc. The diffusion barrier can be formed to a thickness that mitigates Mn diffusion into higher layers of the MTJ; the diffusion barrier thickness is also selected such that magnetic coupling (or strong magnetic coupling) between the natural antiferromagnet and the first and second ferromagnetic materials of the synthetic antiferromagnet is maintained.

A second ferromagnetic layer is formed on the diffusion barrier (312). The first and second ferromagnetic layers can include CoFe or other alloy of Cobalt and Iron.

The remainder of the MTJ can be formed. For example, the reference layer of the synthetic antiferromagnet can be formed (314). The reference layer can be formed on a layer of Ru, which aligns the magnetic spin of reference layer opposite to that of ferromagnetic layer 312. The reference layer can include Co₂₀Fe₆₀B₂₀ or other alloys of Co, Fe, B or Co, Fe.

A tunneling barrier can be formed on the synthetic antiferromagnet (316). The tunneling barrier can include MgO or Al₂O₃. A free layer can be formed on the tunneling barrier (318). The free layer can include Co₂₀Fe₆₀B₂₀ or other alloys of Co, Fe, B or Co, Fe. A cap can be formed on the free layer (320). The cap can be MgO or other metal oxides or refractory metals. A top electrode can be formed on the cap (322).

Forming the various layers can include depositing the alloys or materials in a vacuum environment using sputtering techniques. In some embodiments, forming the MTJ can also include lithographic techniques, deposition techniques, etching, etc. In addition, the materials can be heated and cooled, and in some cases, heated and cooled in the presence of a magnetic field. The MTJ can be annealed after formation.

A plurality of transistors, such as metal-oxide-semiconductor field-effect transistors (MOSFET or simply MOS transistors), may be fabricated on the substrate. In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may consist of a combination of U-shaped structures and planar, non-U-shaped structures. For example, the gate electrode may consist of one or more U-shaped metal layers formed atop one or more planar, non-U-shaped layers.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

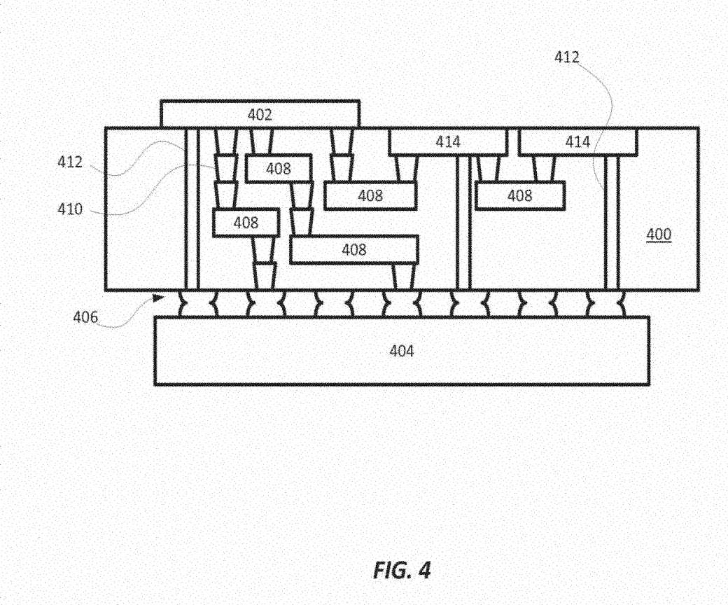

FIG. 4 illustrates an interposer 400 that includes one or more embodiments of the disclosure. The interposer 400 is an intervening substrate used to bridge a first substrate 402 to a second substrate 404. The first substrate 402 may be, for instance, an integrated circuit die. The second substrate 404 may be, for instance, a memory module, a computer motherboard, or another integrated circuit die. Generally, the purpose of an interposer 400 is to spread a connection to a wider pitch or to reroute a connection to a different connection. For example, an interposer 400 may couple an integrated circuit die to a ball grid array (BGA) 406 that can subsequently be coupled to the second substrate 404. In some embodiments, the first and second substrates 402/404 are attached to opposing sides of the interposer 400. In other embodiments, the first and second substrates 402/404 are attached to the same side of the interposer 400. And in further embodiments, three or more substrates are interconnected by way of the interposer 400.

The interposer 400 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 408 and vias 410, including but not limited to through-silicon vias (TSVs) 412. The interposer 400 may further include embedded devices 414, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 400.

In accordance with embodiments of the disclosure, apparatuses or processes disclosed herein may be used in the fabrication of interposer 400.

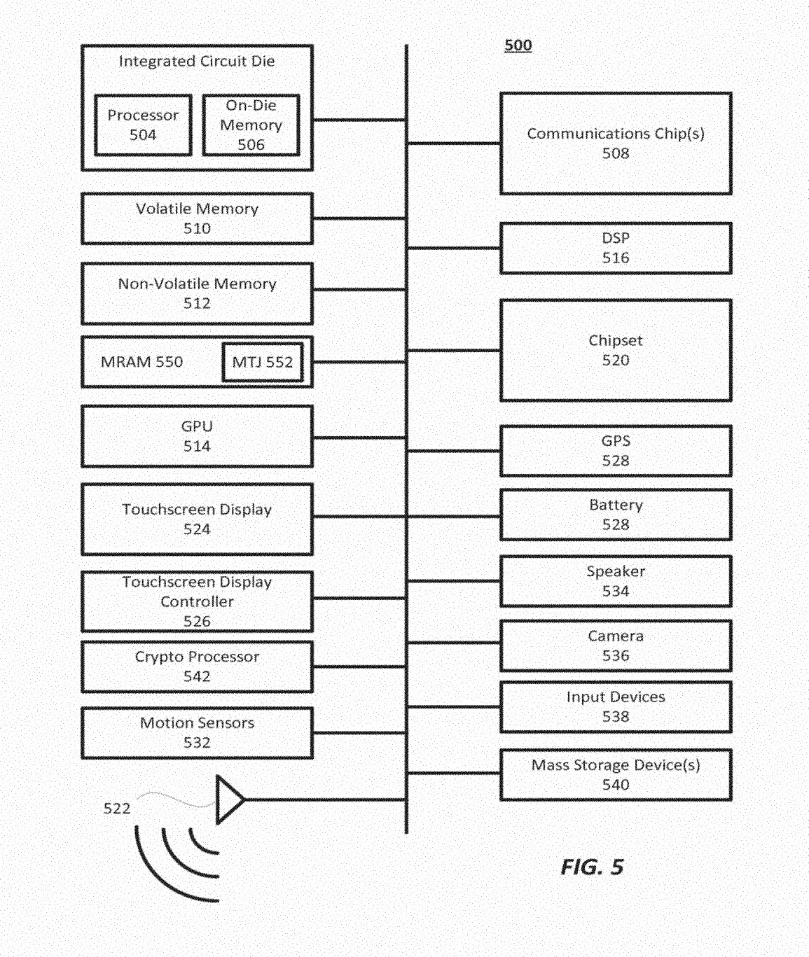

FIG. 5 illustrates a computing device 500 in accordance with one embodiment of the disclosure. The computing device 500 may include a number of components. In one embodiment, these components are attached to one or more motherboards. In an alternate embodiment, some or all of these components are fabricated onto a single system-on-a-chip (SoC) die. The components in the computing device 500 include, but are not limited to, an integrated circuit die 502 and at least one communications logic unit 508. In some implementations the communications logic unit 508 is fabricated within the integrated circuit die 502 while in other implementations the communications logic unit 508 is fabricated in a separate integrated circuit chip that may be bonded to a substrate or motherboard that is shared with or electronically coupled to the integrated circuit die 502. The integrated circuit die 502 may include a CPU 504 as well as on-die memory 506, often used as cache memory, that can be provided by technologies such as embedded DRAM (eDRAM) or spin-transfer torque memory (STTM or STT-MRAM).

Computing device 500 may include other components that may or may not be physically and electrically coupled to the motherboard or fabricated within an SoC die. These other components include, but are not limited to, volatile memory 510 (e.g., DRAM), non-volatile memory 512 (e.g., ROM or flash memory), a graphics processing unit 514 (GPU), a digital signal processor 516, a crypto processor 542 (a specialized processor that executes cryptographic algorithms within hardware), a chipset 520, an antenna 522, a display or a touchscreen display 524, a touchscreen controller 526, a battery 528 or other power source, a power amplifier (not shown), a voltage regulator (not shown), a global positioning system (GPS) device 528, a compass 530, a motion coprocessor or sensors 532 (that may include an accelerometer, a gyroscope, and a compass), a speaker 534, a camera 536, user input devices 538 (such as a keyboard, mouse, stylus, and touchpad), and a mass storage device 540 (such as hard disk drive, compact disk (CD), digital versatile disk (DVD), and so forth).

The non-volatile memory can include a magnetoresistive random-access memory (MRAM) 550. MRAM 550 can include one or more MTJ stacks 552. MTJ stack 552 can be similar to the MTJ stack described in FIG. 2 and include a synthetic antiferromagnet that includes a diffusion barrier between two ferromagnetic layers.

The communications logic unit 508 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 508 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communications logic units 508. For instance, a first communications logic unit 508 may be dedicated to shorter range wireless communications such as Wi-Fi and Bluetooth and a second communications logic unit 508 may be dedicated to longer range wireless communications such as GPS, EDGE, GPRS, CDMA, WiMAX, LTE, Ev-DO, and others.

In various embodiments, the computing device 500 may be a laptop computer, a netbook computer, a notebook computer, an ultrabook computer, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

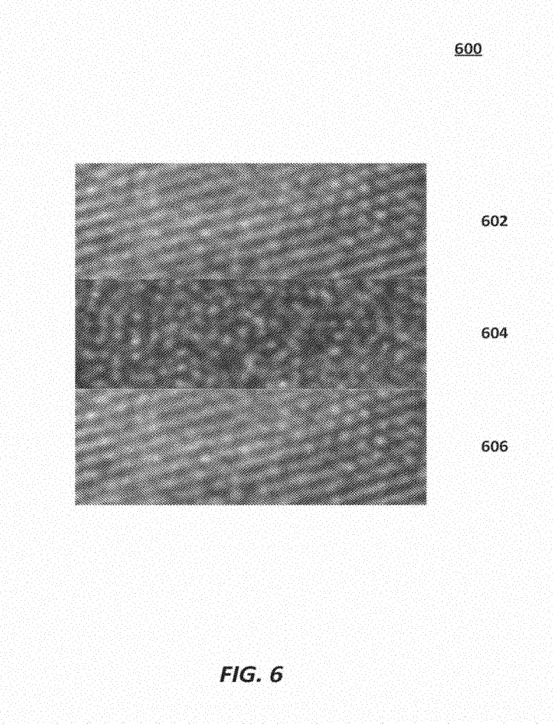

FIG. 6 is an example transmission electron microscopy (TEM) image 600 of a diffusion barrier between two ferromagnetic layers of a magnetic tunneling junction. The TEM image 600 includes a representative image of a first ferromagnetic layer 602, a diffusion barrier 604, and a second ferromagnetic layer 606. The diffusion barrier 604 has a characteristic appears distinguishable in the TEM image 600 from the two adjacent ferromagnetic layer 602 and 604.

The following paragraphs provide examples of various ones of the embodiments disclosed herein.

Example 1 is a magnetic tunneling junction (MTJ) stack that includes an antiferromagnetic layer including manganese (Mn); a ferromagnetic layer; and a diffusion barrier, the diffusion barrier including a material that is a barrier to Mn diffusion, the ferromagnetic layer residing between the antiferromagnetic layer and the diffusion barrier.

Example 2 may include the subject matter of example 1, wherein the diffusion barrier includes a refractory metal.

Example 3 may include the subject matter of any of examples 1 or 2, wherein the diffusion barrier includes one of tantalum, molybdenum, tungsten, niobium, hafnium, zirconium, or titanium.

Example 4 may include the subject matter of any of examples 1-3, wherein the ferromagnetic layer includes a cobalt and iron alloy.

Example 5 may include the subject matter of any of examples 1-4, wherein the ferromagnetic layer is a first ferromagnetic layer, the MTJ stack further including a second ferromagnetic layer including cobalt iron, the diffusion barrier disposed between the first ferromagnetic layer and the second ferromagnetic layer.

Example 6 may include the subject matter of example 5, wherein the first and second ferromagnetic layers are strongly ferromagnetically coupled to the antiferromagnetic layer.

Example 7 may include the subject matter of any of examples 5 or 6, wherein the first and second ferromagnetic layers include a magnetic exchange bias at or above 550 Oersted.

Example 8 may include the subject matter of any of examples 1-7, wherein the diffusion barrier includes a thickness of 1-10 Å.

Example 9 may include the subject matter of any of examples 1-8, wherein the diffusion barrier includes a thickness of 4-6 Å.

Example 10 may include the subject matter of any of examples 1-9, wherein the antiferromagnetic layer includes platinum manganese.

Example 11 is a method of creating a magnetic tunneling junction (MTJ) stack. The method may include forming a first ferromagnetic layer; forming a diffusion barrier on the first ferromagnetic layer; and forming a second ferromagnetic layer.

Example 12 may include the subject matter of example 11, and also include prior to forming the first ferromagnetic layer, forming an antiferromagnetic layer.

Example 13 may include the subject matter of example 12, wherein forming the antiferromagnetic layer includes depositing a seed layer; depositing the antiferromagnetic layer; heating the antiferromagnetic layer to a predetermined temperature; applying a magnetic field to the antiferromagnetic layer; and cooling the antiferromagnetic layer in the presence of the magnetic field.

Example 14 may include the subject matter of any of examples 12 or 13, wherein the antiferromagnetic layer includes platinum manganese.

Example 15 may include the subject matter of any of examples 11-14, wherein the diffusion barrier includes a refractory metal.

Example 16 may include the subject matter of any of examples 11-15, wherein the diffusion barrier includes tantalum.

Example 17 may include the subject matter of any of examples 11-16, wherein forming the diffusion barrier includes sputtering a diffusion barrier material to a thickness in a range between 1-10 Å.

Example 18 may include the subject matter of any of examples 11-17, further including annealing the MTJ stack to a temperature above 400 C.

Example 19 may include the subject matter of any of examples 11-18, wherein the first and second ferromagnetic layers include a cobalt and iron alloy.

Example 20 may include any of the subject matter of examples 11-19, and also include forming a synthetic antiferromagnet, the synthetic antiferromagnet including the first ferromagnetic layer, the diffusion barrier, and the second ferromagnetic layer.

Example 21 is a computing device that includes a processor mounted on a substrate; a communications logic unit within the processor; a memory within the processor; a graphics processing unit within the computing device; an antenna within the computing device; a display on the computing device; a battery within the computing device; a power amplifier within the processor; a voltage regulator within the processor; and a non-volatile memory. The non-volatile memory includes a magnetic random access memory (MRAM). The MRAM includes a magnetic tunneling junction (MTJ) stack including an antiferromagnetic layer including manganese (Mn); a ferromagnetic layer; and a diffusion barrier, the diffusion barrier including a material that is a barrier to Mn diffusion, the ferromagnetic layer residing between the antiferromagnetic layer and the diffusion barrier.

Example 22 may include the subject matter of example 21, wherein the diffusion barrier includes a refractory metal.

Example 23 may include the subject matter of any of examples 21-22, wherein the diffusion barrier includes one of tantalum, molybdenum, tungsten, niobium, hafnium, zirconium, or titanium.

Example 24 may include the subject matter of any of examples 21-23, wherein the ferromagnetic layer includes a cobalt and iron alloy.

Example 25 may include the subject matter of any of examples 21-24, wherein the ferromagnetic layer is a first ferromagnetic layer, the MTJ stack further including a second ferromagnetic layer including cobalt iron, the diffusion barrier disposed between the first ferromagnetic layer and the second ferromagnetic layer.

Example 26 may include the subject matter of example 25, wherein the first and second ferromagnetic layers are strongly ferromagnetically coupled to the antiferromagnetic layer.

Example 27 may include the subject matter of any of examples 25-26, wherein the first and second ferromagnetic layers include a magnetic exchange bias at or above 550 Oersted.

Example 28 may include the subject matter of any of examples 21-27, wherein the diffusion barrier includes a thickness of 1-10 Å.

Example 29 may include the subject matter of any of examples 21-28, wherein the diffusion barrier includes a thickness of 4-6 Å.

Example 30 may include the subject matter of any of examples 21-29, wherein the antiferromagnetic layer includes platinum manganese.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

1. A magnetic tunneling junction (MTJ) stack comprising:
an antiferromagnetic layer comprising manganese (Mn);
a ferromagnetic layer; and
a diffusion barrier, the diffusion barrier comprising a material that is a barrier to Mn diffusion, the ferromagnetic layer residing between the antiferromagnetic layer and the diffusion barrier.

2. The MTJ stack of claim 1, wherein the diffusion barrier comprises a refractory metal.

3. The MTJ stack of claim 1, wherein the diffusion barrier comprises one of tantalum, molybdenum, tungsten, niobium, hafnium, zirconium, or titanium.

4. The MTJ stack of claim 1, wherein the ferromagnetic layer comprises an alloy of cobalt and iron.

5. The MTJ stack of claim 1, wherein the ferromagnetic layer is a first ferromagnetic layer, the MTJ stack further comprising a second ferromagnetic layer comprising an alloy of cobalt and iron, the diffusion barrier disposed between the first ferromagnetic layer and the second ferromagnetic layer.

6. The MTJ stack of claim 5, wherein the first and second ferromagnetic layers are strongly ferromagnetically coupled to the antiferromagnetic layer.

7. The MTJ stack of claim 6, wherein the first and second ferromagnetic layers comprise a magnetic exchange bias at or above 550 Oersted.

8. The MTJ stack of claim 1, wherein the diffusion barrier comprises a thickness of 1-10 Å.

9. The MTJ stack of claim 1, wherein the antiferromagnetic layer comprises platinum manganese.

10. A method of creating a magnetic tunneling junction (MTJ) stack, the method comprising:
forming an antiferromagnetic layer;
forming a first ferromagnetic layer;
forming a diffusion barrier on the first ferromagnetic layer; and
forming a second ferromagnetic layer.

11. The method of claim 10, wherein forming the antiferromagnetic layer comprises:
depositing a seed layer;
depositing the antiferromagnetic layer;
heating the antiferromagnetic layer to a predetermined temperature;
applying a magnetic field to the antiferromagnetic layer; and
cooling the antiferromagnetic layer in the presence of the magnetic field.

12. The method of claim 10, wherein the antiferromagnetic layer comprises platinum manganese.

13. The method of claim 10, wherein the diffusion barrier comprises a refractory metal.

14. The method of claim 10, wherein the diffusion barrier comprises one of tantalum, molybdenum, tungsten, niobium, hafnium, zirconium, or titanium.

15. The method of claim 10, wherein forming the diffusion barrier comprises sputtering a diffusion barrier material to a thickness in a range between 1-10 Å.

16. The method of claim 10, further comprising annealing the MTJ stack to a temperature above 400 C.

17. The method of claim 10, wherein the first and second ferromagnetic layers comprise an alloy of cobalt and iron.

18. The method of claim 10, further comprising forming a synthetic antiferromagnet, the synthetic antiferromagnet comprising the first ferromagnetic layer, the diffusion barrier, and the second ferromagnetic layer, a ruthenium layer and a reference layer.

19. A computing device comprising:
a processor mounted on a substrate;
a communications logic unit within the processor;
a memory within the processor;
a graphics processing unit within the computing device;
an antenna within the computing device;
a display on the computing device;
a battery within the computing device;
a power amplifier within the processor;
a voltage regulator within the processor; and
a non-volatile memory;
wherein the non-volatile memory comprises:
a magnetic tunneling junction (MTJ) stack comprising:
an antiferromagnetic layer comprising platinum manganese (PtMN);
a ferromagnetic layer; and
a diffusion barrier, the diffusion barrier comprising a material that is a barrier to Mn diffusion, the ferromagnetic layer residing between the antiferromagnetic layer and the diffusion barrier;
wherein the diffusion barrier comprises a refractory metal.

20. The computing device of claim 19, wherein the diffusion barrier comprises one of tantalum, molybdenum, tungsten, niobium, hafnium, zirconium, or titanium.

21. The computing device of claim 19, wherein the ferromagnetic layer comprises an alloy of cobalt and iron.

22. The computing device of claim 19, wherein the ferromagnetic layer is a first ferromagnetic layer, the MTJ stack further comprising a second ferromagnetic layer comprising an alloy of cobalt and iron, the diffusion barrier disposed between the first ferromagnetic layer and the second ferromagnetic layer.

23. The computing device of claim 22, wherein the first and second ferromagnetic layers are strongly ferromagnetically coupled to the antiferromagnetic layer.

24. The computing device of claim 23, wherein the first and second ferromagnetic layers comprise a magnetic exchange bias at or above 550 Oersted.

25. The computing device of claim 19, wherein the diffusion barrier comprises a thickness of 1-10 Å.
